(19) United States
(12) Patent Application Publication
(10) Pub. No.: US 2009/0023297 A1
(43) Pub. Date: Jan. 22, 2009

(54) METHOD AND APPARATUS FOR HMDS TREATMENT OF SUBSTRATE EDGES

(75) Inventor: Mohsen Salek, Saratoga, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: SOKUDO CO., LTD., Kyoto (JP)

(21) Appl. No.: 11/779,844

(22) Filed: Jul. 18, 2007

(51) Int. Cl. H01L 21/30

(52) U.S. Cl. 438/758; 118/326; 257/E21.211

(57) ABSTRACT

A system for dispensing an adhesion promoting chemical includes a support plate configured to support a substrate and a dispense nozzle in fluid communication with a source of the adhesion promoting chemical, for example, HMDS. The dispense nozzle is positioned adjacent a peripheral portion of the substrate and at a first radial distance. The system also includes an exhaust aperture in fluid communication with a system exhaust. The exhaust aperture is positioned adjacent to dispense nozzle and at a second radial distance greater than the first radial distance.

### BACKGROUND OF THE INVENTION

The present invention relates generally to the field of substrate processing equipment. More particularly, the present invention relates to methods and systems used in photolithographic processing. Merely by way of example, the system and related methods of the present invention provide for treatment of a substrate edge region with hexamethyldisilazane (HMDS) in order to improve adhesion of a bottom anti-reflection coatings to the substrate. In particular, embodiments of the present invention provide benefits during immersion lithography processes. The method and apparatus can also be applied to other coating used during photolithographic processing.

Modern integrated circuits contain millions of individual elements that are formed by patterning the materials, such as silicon, metal and dielectric layers, that make up the integrated circuit to sizes that are small fractions of a micrometer. The technique used throughout the industry for forming such patterns is photolithography. A typical photolithography process sequence generally includes depositing one or more uniform photoresist (resist) layers on the surface of a substrate, drying and curing the deposited layers, patterning the substrate by exposing the photoresist layer to radiation that is suitable for modifying the exposed layer and then developing the patterned photoresist layer.

It is common in the semiconductor industry for many of the steps associated with the photolithography process to be performed in a multi-chamber processing system (e.g., a cluster tool) that has the capability to sequentially process semiconductor wafers in a controlled manner. One example of a cluster tool that is used to deposit (i.e., coat) and develop a photoresist material is commonly referred to as a track lithography tool. Such track lithography tools typically include a mainframe that houses multiple chambers (which are sometimes referred to herein as stations) dedicated to performing the various tasks associated with pre- and post-lithography processing. There are typically both wet and dry processing chambers within track lithography tools. Wet chambers include coat and/or develop bowls, while dry chambers include thermal control units that house bake and/or chill plates.

Track lithography tools may be operatively coupled to a scanner that uses an immersion exposure process. Immersion processing, also referred to as immersion lithography, is being implemented at the 45 nm technology and lower node in semiconductor manufacturing. In immersion lithography, a liquid layer (e.g., water) is positioned between the lens and the wafer surface during the wafer exposure process. The index of refraction of the liquid layer improves the depth of focus and reduces the minimum line width achievable during the exposure process. The ability of immersion lithography to print smaller structures is similar to the phenomenon of placing oil droplets on microscope slides to increase the effective magnification.

Despite the benefits provided by immersion lithography, there is a need in the art for methods and systems to reduce processing complications introduced by the immersion lithography process.

### SUMMARY OF THE INVENTION

According to an embodiment of the present invention, a system for dispensing an adhesion promoting chemical is provided. The system includes a support plate configured to support a substrate and a dispense nozzle in fluid communication with a source of the adhesion promoting chemical. As an example, the adhesion promoting chemical may be HMDS. The dispense nozzle is positioned adjacent a peripheral portion of the substrate and at a first radial distance. The system also includes an exhaust aperture in fluid communication with a system exhaust. The exhaust aperture is positioned adjacent to dispense nozzle and at a second radial distance greater than the first radial distance.

According to another embodiment of the present invention, a method of treating a substrate with an adhesion promoting chemical is provided. The method includes positioning the substrate on a support plate and flowing the adhesion promoting chemical into a region adjacent the substrate. The adhesion promoting chemical makes contact with a peripheral portion of the substrate while maintaining a central portion of the substrate substantially free from contact with the adhesion promoting chemical. The method also includes passing the adhesion promoting chemical by the peripheral portion of the substrate and exhausting the adhesion promoting chemical from the region adjacent the substrate.

According to a specific embodiment of the present invention, a track lithography tool is provided. The track lithography tool includes a robot and a thermal treatment unit serviced by the robot. The track lithography tool also includes a coating unit serviced by the robot and an adhesion treatment unit serviced by the robot. The adhesion treatment unit includes a support plate configured to support a substrate and a dispense nozzle in fluid communication with a source of the adhesion promoting chemical. The dispense nozzle is positioned adjacent a peripheral portion of the substrate and at a first radial distance. The adhesion treatment unit also includes an exhaust aperture in fluid communication with a system exhaust. The exhaust aperture is positioned adjacent to dispense nozzle and at a second radial distance greater than the first radial distance.

Many benefits are achieved by way of the present invention over conventional techniques. For example, embodiments of the present invention provide for increases in adhesion of coating layers on the wafer edge while reducing the occurrence of defects on the wafer surface resulting from the process of dispensing an adhesion promoting chemical. Edge peeling of coating layers is reduced by embodiments of the present invention. Additionally, embodiments of the present invention reduce the amount of adhesion promoting chemicals used during processing operations. Depending upon the embodiment, one or more of these benefits, as well as other benefits, may be achieved. These and other benefits will be described in more detail throughout the present specification and more particularly below in conjunction with the following drawings.

### BRIEF DESCRIPTION OF THE DRAWINGS

FIG. 1 is a simplified architecture of a track lithography tool coupled to an immersion scanner;

FIG. 2 is a simplified illustration of a portion of a substrate during an immersion exposure process;

FIG. 3 is a simplified schematic diagram illustrating a dispense apparatus according to an embodiment of the present invention;

FIG. 4 is a simplified schematic diagram illustrating of a portion of a dispense module according to an embodiment of the present invention;

FIGS. 5A and 5B are simplified perspective drawings illustrating an integrated dispense apparatus according to an embodiment of the present invention;

FIG. 6 is a simplified flowchart illustrating a method of dispensing an adhesion promoting chemical according to an embodiment of the present invention; and

FIG. 7 is a simplified schematic diagram illustrating a dispense module according to an embodiment of the present invention.

### DETAILED DESCRIPTION OF SPECIFIC EMBODIMENTS

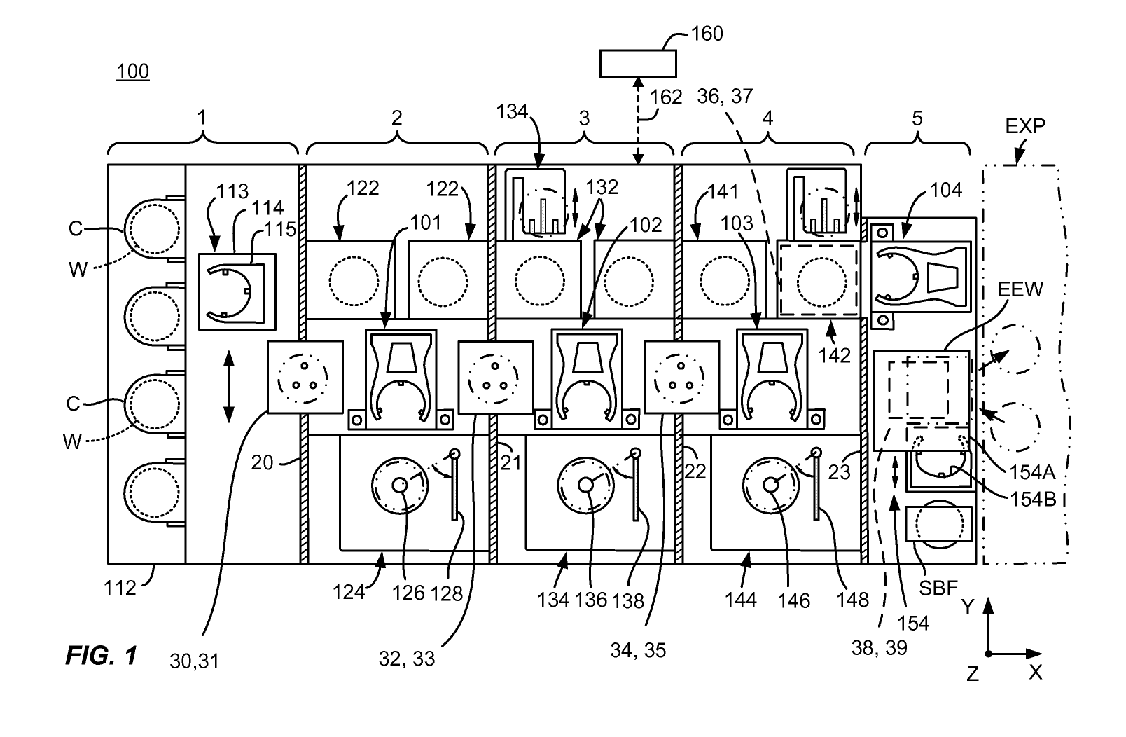

FIG. 1 is a plan view of a track lithography tool according to an embodiment of the present invention. In the embodiment illustrated in FIG. 1, the track lithography tool is coupled to an immersion scanner. An XYZ rectangular coordinate system in which an XY plane is defined as the horizontal plane and a Z axis is defined to extend in the vertical direction is additionally shown in FIG. 1 for purposes of clarifying the directional relationship therebetween.

In a particular embodiment, the track lithography tool is used to form, through use of a coating process, an anti-reflection (AR) and a photoresist film on substrates, for example, semiconductor wafers. The track lithography tool is also used to perform a development process on the substrates after they have been subjected to a pattern exposure process. The substrates processed by the track lithography tool are not limited to semiconductor wafers, but may include glass substrates for a liquid crystal display device, and the like.

The track lithography tool 100 illustrated in FIG. 1 includes an factory interface block 1, a BARC (Bottom Anti-Reflection Coating) block 2, a resist coating block 3, a development processing block 4, and a scanner interface block 5. In the track lithography tool, the five processing blocks 1 to 5 are arranged in a side-by-side relation. An exposure unit (or stepper) EXP, which is an external apparatus separate from the track lithography tool is provided and coupled to the scanner interface block 5. Additionally, the track lithography tool and the exposure unit EXP are connected via LAN lines 162 to a host computer 160.

The factory interface block 1 is a processing block for transferring unprocessed substrates received from outside of the track lithography tool to the BARC block 2 and the resist coating block 3. The factory interface block 1 is also useful for transporting processed substrates received from the development processing block 4 to the outside of the track lithography tool. The factory interface block 1 includes a table 112 configured to receive a number of (in the illustrated embodiment, four) cassettes (or carriers) C, and a substrate transfer mechanism 113 for retrieving an unprocessed substrate W from each of the cassettes C and for storing a processed substrate W in each of the cassettes C. The substrate transfer mechanism 113 includes a movable base 114, which is movable in the Y direction (horizontally) along the table 112, and a robot arm 115 mounted on the movable base 114.

The robot arm 115 is configured to support a substrate W in a horizontal position during wafer transfer operations. Additionally, the robot arm 115 is capable of moving in the Z direction (vertically) in relation to the movable base 114, pivoting within a horizontal plane, and translating back and forth in the direction of the pivot radius. Thus, using the substrate transfer mechanism 113, the holding arm 115 is able to gain access to each of the cassettes C, retrieve an unprocessed substrate W out of each cassette C, and store a processed substrate W in each cassette C. The cassettes C may be one or several types including: an SMIF (standard mechanical interface) pod; an OC (open cassette), which exposes stored substrates W to the atmosphere; or a FOUP (front opening unified pod), which stores substrates W in an enclosed or sealed space.

The BARC block 2 is positioned adjacent to the factory interface block 1. Partition 20 may be used to provide an atmospheric seal between the factory interface block 1 and the BARC block 2. The partition 20 is provided with a pair of vertically arranged substrate rest parts 30 and 31 each used as a transfer position when transferring a substrate W between the factory interface block 1 and the BARC block 2.

The upper substrate rest part 30 is used for the transport of a substrate W from the factory interface block 1 to the BARC block 2. The substrate rest part 30 includes three support pins. The substrate transfer mechanism 113 of the factory interface block 1 places an unprocessed substrate W, which was taken out of one of the cassettes C, onto the three support pins of the substrate rest part 30. A transport robot 101 in the BARC block 2 (described more fully below) is configured to receive the substrate W placed on the substrate rest part 30. The lower substrate rest part 31, on the other hand, is used for the transport of a substrate W from the BARC block 2 to the factory interface block 1. The substrate rest part 31 also includes three support pins. The transport robot 101 in the BARC block 2 places a processed substrate W onto the three support pins of the substrate rest part 31. The substrate transfer mechanism 113 is configured to receive the substrate W placed on the substrate rest part 31 and then store the substrate W in one of the cassettes C. Pairs of substrate rest parts 32-39 (which are described more fully below) are similar in construction and operate in an analogous manner to the pair of substrate rest parts 30 and 31.

The substrate rest parts 30 and 31 extend through the partition 20. Each of the substrate rest parts 30 and 31 include an optical sensor (not shown) for detecting the presence or absence of a substrate W thereon. Based on a detection signal from each of the sensors, control of the substrate transfer mechanism 113 and the transport robot 101 of the BARC block 2 is exercised to transfer and receive a substrate W to and from the substrate rest parts 30 and 31.

Referring to FIG. 1 again, BARC block 2 is also included in the track lithography tool 100. The BARC block 2 is a processing block for forming an AR film (also referred to as a BARC) on a substrate using a coating process. The BARC is positioned in the film stack under the photoresist film, which is subsequently deposited. The BARC reduces standing waves or halation occurring during exposure. The BARC block 2 includes a bottom coating processor 124 configured to coat the surface of a substrate W with the AR film, a pair of thermal processing towers 122 for performing one or more thermal processes that accompany the formation of the AR film, and the transport robot 101, which is used in transferring and receiving a substrate W to and from the bottom coating processor 124 and the pair of thermal processing towers 122.

In the BARC block 2, the bottom coating processor 124 and the pair of thermal processing towers 122 are arranged on opposite sides of the transport robot 101. Specifically, the bottom coating processor 124 is on the front side of the track lithography tool and the pair of thermal processing towers 122 are on the rear side thereof. Additionally, a thermal barrier (not shown) is provided on the front side of the pair of thermal processing towers 122. Thus, the thermal crosstalk from the pair of thermal processing towers 122 to the bottom coating processor 124 is reduced by the spacing between the bottom coating processor 124 and the pair of thermal processing towers 122 and through the use of the thermal barrier.

Generally, the bottom coating processor 124 includes three vertically stacked coating processing units that are similar in construction. The three coating processing units are collectively referred to as the bottom coating processor 124, unless otherwise identified. Each of the coating processing units includes a spin chuck 126 on which the substrate W is rotated in a substantially horizontal plane while the substrate W is held in a substantially horizontal position through suction. Each coating processing unit also includes a coating nozzle 128 used to apply a coating solution for the AR film onto the substrate W held on the spin chuck 126, a spin motor (not shown) configured to rotatably drive the spin chuck 126, a cup (not shown) surrounding the substrate W held on the spin chuck 22, and the like.

The thermal processing towers 122 include a number of bake plates used to heat a substrate W to a predetermined temperature and a number of cool plates used to cool a heated substrate down to a predetermined temperature and thereafter maintain the substrate at the predetermined temperature. The bake plates and cool plates are vertically stacked, with the cool plates generally mounted underneath the bake plates. The thermal processing towers may also include a number of vertically stacked adhesion promotion units (e.g., HMDS treatment units). Vertical stacking of processing units reduces the tool footprint and reduces the amount of ancillary equipment (e.g., temperature and humidity control apparatus, electrical service, and the like).

Referring once again to FIG. 1, the resist coating block 3 is a processing block for forming a resist film on the substrate W after formation of the AR film in the BARC block 2. In a particular embodiment, a chemically amplified resist is used as the photoresist. The resist coating block 3 includes a resist coating processor 134 used to form the resist film on top of the AR film, a pair of thermal processing towers 132 for performing one or more thermal processes accompanying the resist coating process, and the transport robot 102, which is used to transfer and receive a substrate W to and from the resist coating processor 134 and the pair of thermal processing towers 132.

Similar to the configuration of the processors in BARC block 2, the resist coating processor 134 and the pair of thermal processing towers 132 are arranged on opposite sides of the transport robot 102. A thermal barrier (not shown) is provided to reduce thermal crosstalk between processors. Generally, the resist coating processor 134 includes three vertically stacked coating processing units that are similar in construction. Each of the coating processing units includes a spin chuck 136, a coating nozzle 138 for applying a resist coating to the substrate W, a spin motor (not shown), a cup (not shown), and the like.

The thermal processing towers 132 include a number of vertically stacked bake chambers and cool plates. In a particular embodiment, the thermal processing tower closest to the factory interface block 1 includes bake chambers and the thermal processing tower farthest from the factory interface block 1 includes cool plates. In the embodiment illustrated in FIG. 1, the bake chambers include a vertically stacked bake plate and temporary substrate holder as well as a local transport mechanism 134 configured to move vertically and horizontally to transport a substrate W between the bake plate and the temporary substrate holder and may include an actively chilled transport arm. The transport robot 102 is identical in construction to the transport robot 101 in some embodiments. The transport robot 102 is able to independently access substrate rest parts 32 and 33, the thermal processing towers 132, the coating processing units provided in the resist coating processor 134, and the substrate rest parts 34 and 35.

The development processing block 4 is positioned between the resist coating block 3 and the scanner interface block 5. A partition 22 for sealing the development processing block from the atmosphere of the resist coating block 3 is provided. The upper substrate rest part 34 is used to transport a substrate W from the resist coating block 3 to the development processing block 4. The lower substrate rest part 35, on the other hand, is used to transport a substrate W from the development processing block 4 to the resist coating block 3. As described above, substrate rest parts 32-39 may include an optical sensor for detecting the presence or absence of a substrate W thereon. Based on a detection signal from each of the sensors, control of the various substrate transfer mechanisms and transport robots of the various processing blocks is exercised during substrate transfer processes.

The development processing block 4 includes a development processor 144 for applying a developing solution to a substrate W after exposure in the scanner EXP, a pair of thermal processing towers 141 and 142, and transport robot 103. The development processor 144 includes five vertically stacked development processing units that are similar in construction to each other. Each of the development processing units includes a spin chuck 146, a nozzle 148 for applying developer to a substrate W, a spin motor (not shown), a cup (not shown), and the like.

Thermal processing tower 142 includes bake chambers and cool plates as described above. Additionally, thermal processing tower 142 is accessible to both transport robot 103 as well as transport robot 104. Thermal processing unit 141 is accessible to transport robot 103. Additionally, thermal processing tower 142 includes substrate rest parts 36 and 37, which are used when transferring substrates to and from the development processing block 4 and the scanner interface block 5.

The interface block 5 is used to transfer a coated substrate W to the scanner EXP and to transfer an exposed substrate to the development processing block 5. The interface block 5 in this illustrated embodiment includes a transport mechanism 154 for transferring and receiving a substrate W to and from the exposure unit EXP, a pair of edge exposure units EEW for exposing the periphery of a coated substrate, and transport robot 104. Substrate rest parts 39 and 39 are provided along with the pair of edge exposure units EEW for transferring substrates to and from the scanner and the development processing unit 4.

The transport mechanism 154 includes a movable base 154A and a holding arm 154B mounted on the movable base 154A. The holding arm 154B is capable of moving vertically, pivoting, and moving back and forth in the direction of the pivot radius relative to the movable base 154A. The send buffer SBF is provided to temporarily store a substrate W prior to the exposure process if the exposure unit EXP is unable to accept the substrate W, and includes a cabinet capable of storing a plurality of substrates W in tiers.

Controller 160 is used to control all of the components and processes performed in the cluster tool. The controller 160 is generally adapted to communicate with the scanner 5, monitor and control aspects of the processes performed in the cluster tool, and is adapted to control all aspects of the complete substrate processing sequence. The controller 160, which is typically a microprocessor-based controller, is configured to receive inputs from a user and/or various sensors in one of the processing chambers and appropriately control the processing chamber components in accordance with the various inputs and software instructions retained in the controller's memory. The controller 160 generally contains memory and a CPU (not shown) which are utilized by the controller to retain various programs, process the programs, and execute the programs when necessary. The memory (not shown) is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits (not shown) are also connected to the CPU for supporting the processor in a conventional manner. The support circuits may include cache, power supplies, clock circuits, input/output circuitry, subsystems, and the like all well known in the art. A program (or computer instructions) readable by the controller 160 determines which tasks are performable in the processing chambers. Preferably, the program is software readable by the controller 160 and includes instructions to monitor and control the process based on defined rules and input data.

Additional description of a substrate processing apparatus in accordance with embodiments of the present invention is provided in U.S. Patent Application Publication No. 2006/0245855, entitled “Substrate Processing Apparatus,” the disclosure of which is hereby incorporated by reference in its entirety. Although embodiments of the present invention are described herein in the context of the track lithography tool illustrated in FIG. 1, other architectures for track lithography tools are included within the scope of embodiments of the present invention. For example, track lithography tools utilizing Cartesian architectures are suitable for use with embodiments as described throughout the present specification. In a particular embodiment, implementation is performed for an RF³i, available from Sokudo Co., Ltd. of Kyoto, Japan.

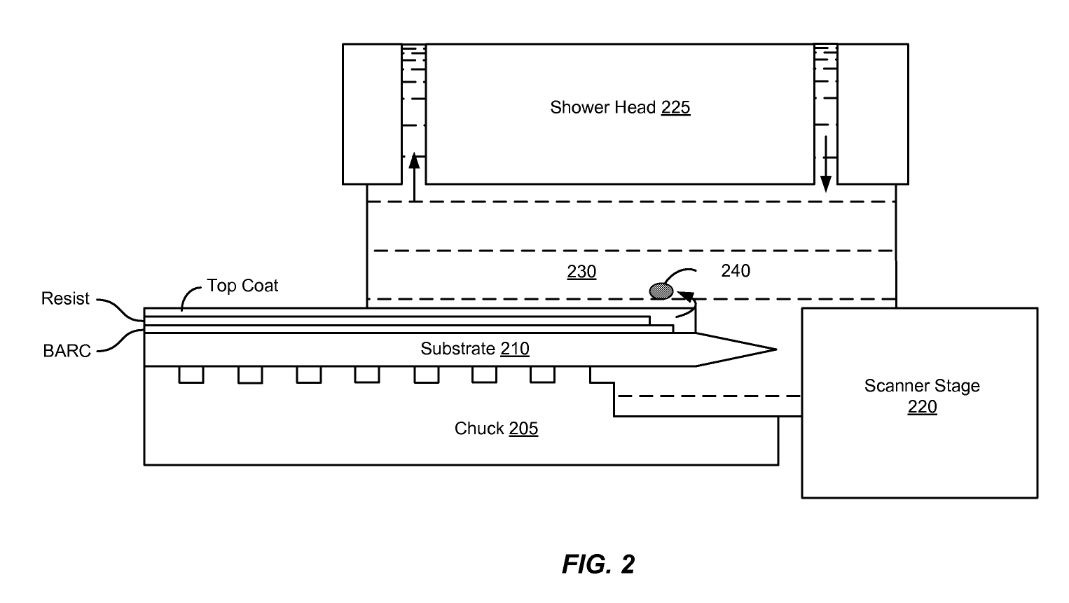

FIG. 2 is a simplified illustration of a portion of a substrate during an immersion exposure process. In immersion lithography, the wafer or substrate 210 is placed on a chuck 205 that flattens the wafer to improve exposure accuracy. The chuck may be a vacuum chuck, electrostatic chuck, or the like. In the system illustrated in FIG. 2, the scanner stage 220 moves back and forth across the wafer surface during the exposure process. As examples, the scanner stage in ASML scanners moves at up to 550 mm/s and the scanner stage in Nikon scanners moves at up to 400 mm/s. The motion of the scanner stage 220 can create a lateral flow of the immersion liquid (e.g., water) 230 across the surface of the wafer and across the wafer bevel. In some cases, the flow of water at the wafer bevel can lift the BARC or other films from the wafer, causing peeling of the BARC or other films formed on the surface of the wafer as illustrated by the arrow at the wafer edge in FIG. 2. When peeling occurs, it generates debris and particles (e.g., particle 240) that result in defects. It is believed that this debris is transported onto the top surface of the wafer, resulting in printing defects that reduce the device yield. Embodiments of the present invention are not limited by this theory as other mechanisms may create additional defects or contribute to the aforementioned defect formation process.

Wetting wafers with dehydrating substances prior to spinning on BARC or photoresist is a technique that can be used to improve the adhesion of BARC or photoresist to the wafer. The most common chemical used for this purpose is HMDS. HMDS improves adhesion by removing water from the wafer and increasing the wettability of the surface (e.g., by reducing the contact angle between BARC and the wafer). The HMDS (sometimes in a vapor phase) reacts with the wafer to form a strong bond to the surface. Free bonds are left which readily react with the BARC or photoresist, enhancing the adhesion of the deposited layers. While HMDS is usually not used for most BARC layers, since BARC layers are generally inorganic, HMDS is used for photoresist and other organic layers. Some embodiments of the present invention promote the adhesion of the photoresist, top coat, or other layers to the edge of the wafer while most of the remaining wafer surface is coated with a BARC layer.

Embodiments of the present invention improve BARC adhesion and reduce edge peeling by pre-treating portions of the wafer with an adhesion promoting material (e.g., HMDS) prior to BARC deposition. Studies by the inventor and assignee have demonstrated that pre-treatment with HMDS prior to BARC deposition reduces edge peeling. However, in some process sequences, some of the benefits provided by the use of HMDS to promote BARC adhesion may be offset by the introduction of defects during the HMDS coating process.

Since peeling is generally believed to be initiated at the edges of the deposited layers, treatment of the entire wafer surface with the adhesion promoting material (e.g., HMDS) is not necessary according to embodiments of the present invention. As described throughout the present specification, portions of the substrate are treated with HMDS or other adhesion promoting chemicals to reduce BARC peeling while concurrently reducing the incidence of defects across the wafer surface. In a particular embodiment, a peripheral edge region of the substrate is treated with HMDS prior to coating with BARC. Treatment of the substrate edges with HMDS reduces BARC peeling as well as peeling of other layers formed above the BARC, for example, photoresist, top coat, and the like. Only a portion of the substrate is treated with HMDS (e.g., the peripheral edge portion), thereby preventing formation of HMDS related defects on central portions of the substrate. Thus, embodiments of the present invention provide adhesion promotion benefits while reducing the incidence of defects by treating the substrate edges with HMDS while maintaining other portions of the substrate free from contact with HMDS.

In addition to HMDS, other adhesion promoting chemicals, including trimethylsilydiethylamine (TMSDEA) and N,N-diethylaminotrimethylsilane (DEATS), are included within the scope of embodiments of the present invention. One of ordinary skill in the art would recognize many variations, modifications, and alternatives.

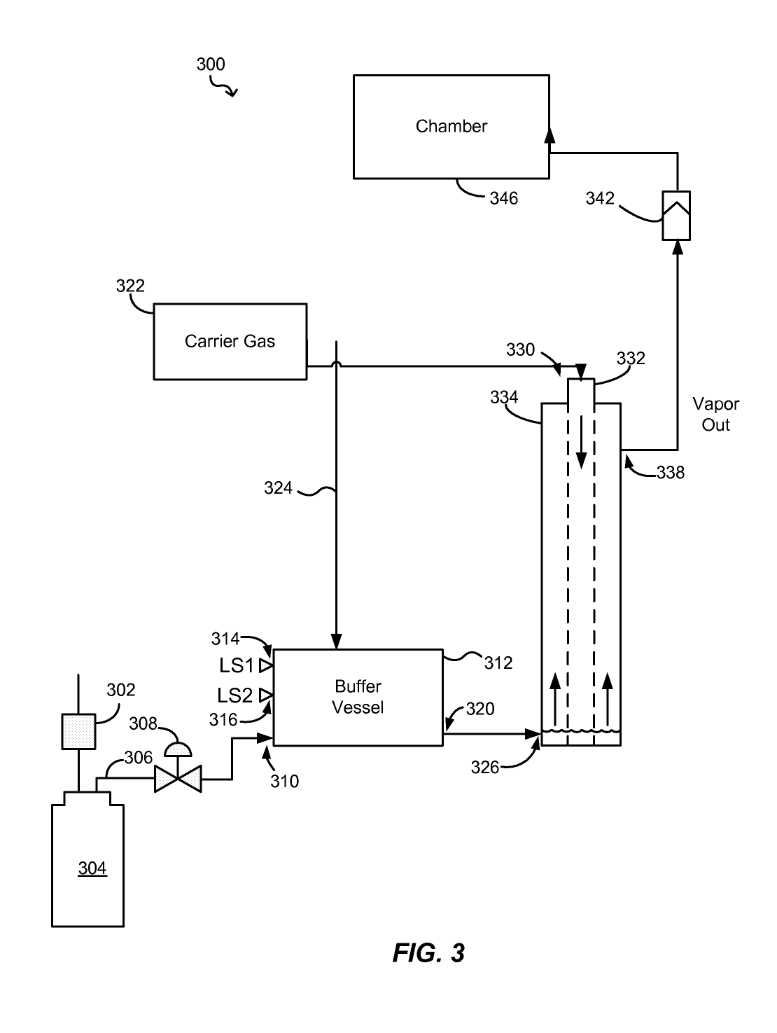

FIG. 3 is a simplified schematic illustration of a dispense module according to an embodiment of the present invention. Pressure in the buffer vessel is equalized to prevent negative pressure in the buffer vessel. The size of the buffer vessel insures that a sufficient volume of the photolithography chemical vapor is provided to a chamber to coat an entire lot of wafers when a photolithography chemical source is empty.

In the system of FIG. 3, a pressure valve 302 used to apply a pressurized flow of gas is coupled to a chemical source bottle 304 containing liquid photolithography chemical (e.g. HMDS) to be dispensed into a chamber 346 as a vapor. The output line from the source bottle 304 is coupled to a flow control valve 308 in order to regulate the flow of the photolithography chemical in a fluid line 306. A buffer vessel 312 for receiving and temporarily storing the liquid photolithography chemical includes an input port 310, coupled to the fluid line 306, and an output port 320.

The buffer vessel 312 also includes level sensor LS1 (314) and level sensor LS2 (316) for regulating the volume of liquid photolithography chemical present in the buffer vessel 312. The level sensors 314 and 316 are activated when a volume of liquid photolithography chemical in the buffer vessel 312 surpasses the level indicated by the corresponding level sensors 314 and 316. In one embodiment, the level sensor LS1 314 operates in conjunction with the flow control valve 308 to regulate the volume of liquid photolithography chemical in the buffer vessel 312. For example, when the level sensor LS1 314 is activated, the flow control valve 308 is closed because a sufficient volume of liquid photolithography chemical is present in the buffer vessel 312. When the level sensor LS1 314 is not activated, the flow control valve 308 is opened for a set time period to allow a volume of liquid photolithography chemical to flow into the buffer vessel 312. If the level sensor LS1 314 is not activated after the time period has elapsed, then the chemical source bottle 304 is empty.

The size of the buffer vessel 312 is selected such that a sufficient volume of photolithography chemical vapor is delivered to the chamber 346 to coat an entire lot of wafers (e.g. 25 wafers) when there is no longer any photolithography chemical in the source bottle 304. In one embodiment, the level sensor LS2 316 is activated when there is a sufficient amount of photolithography chemical in the buffer vessel 312 to coat an entire lot of wafers present in the chamber 346. In one embodiment, the size of the buffer vessel 312 is selected to be in the range of 10-30 ml. Of course, the particular volume will depend on the particular application. One of ordinary skill in the art would recognize many variations, modifications, and alternatives.

A carrier gas source 322 provides carrier gas, such as nitrogen (N₂), to a vapor tube 330. A pressure equalization line 324 is provided between the carrier gas source 322 and the buffer vessel 312 such that the pressure in the buffer vessel 312 is equalized. The equalized pressure insures that negative pressure is not applied to the buffer vessel 312. The liquid photolithography chemical exits the output port 320 of the buffer vessel 312 and enters the vapor tube 330 through an input port 326. The liquid photolithography chemical accumulates in a lower portion of the vapor tube 330.

The vapor tube 330 is concentric and includes an inner column 332 and an outer column 334. In one embodiment, the wall between the inner column 332 and the outer column 334 is porous. The carrier gas is provided to the inner column 332 of the vapor tube 330. The carrier gas moves down the vapor tube 330 and reacts with the liquid photolithography chemical causing the chemical to vaporize. Thus, the buffer vessel 312 and the vapor tube 330 are configured to behave as a diffusion vaporizer. The photolithography chemical vapor exits the vapor tube 330 via an output port 338.

A shut off valve 342 may be coupled to the fluid line running from the output port 338 of the vapor tube 330. The photolithography chemical vapor is delivered to the chamber 346 from the shut off valve 342. The chemical vapor may then coat wafers that are positioned in the chamber 346.

Additional description related to methods and systems for dispensing HMDS onto portions of the wafer surface are provided in co-pending and commonly assigned U.S. patent application Ser. No. 11/693,642, entitled “Method and Apparatus for Dispense of Chemical Vapor in a Track Lithography Tool,” filed on Mar. 29, 2007, the disclosure of which is incorporated herein by reference for all purposes. Although a bubbler system is illustrated in FIG. 3, embodiments of the present invention are not limited to bubbler-type systems. Other delivery systems that provide adhesion promoting chemicals to the surface of the substrate are included within the scope of the present invention.

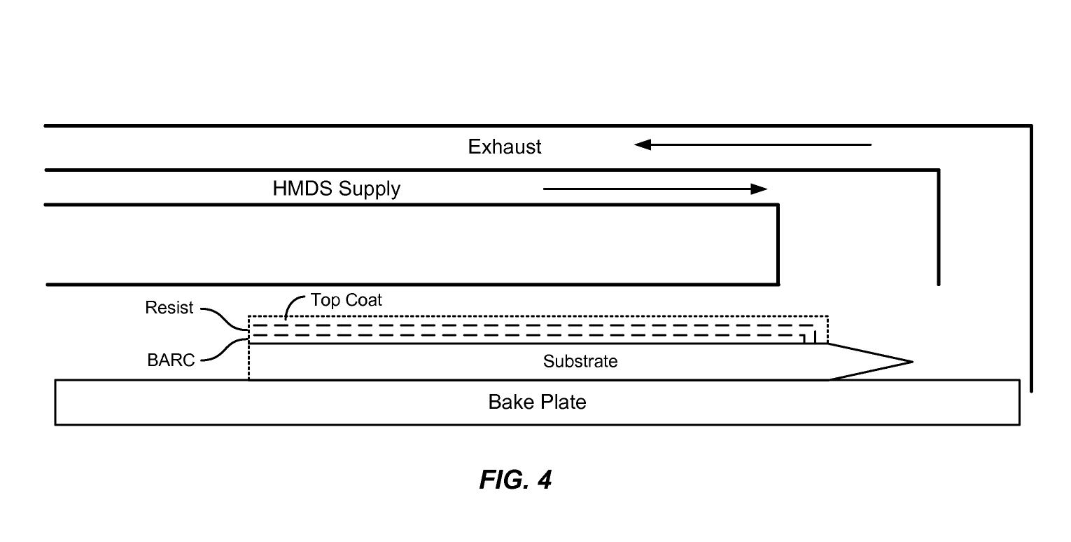

FIG. 4 is a simplified schematic diagram illustrating of a portion of a dispense module according to an embodiment of the present invention. The dispense module is used to dispense an adhesion promoting material onto a substrate prior to BARC deposition. Substrate 405 is supported by a substrate support 402. The support plate may provide for heating and/or cooling of the substrate prior to, during, and/or after the HMDS treatment process. Additional description of bake plates and chill plates useful for such thermal processes are provided in commonly assigned U.S. Patent Application Publication No. 2006/0237433, published on Oct. 6, 2006, the disclosure of which is incorporated herein by reference in its entirety for all purposes. The coating layers BARC, resist, and Top Coat are illustrated with dashed lines to provide a point of reference for the illustrated dispense module. In some embodiments, adhesion promotion processing is performed prior to deposition of the BARC layer. In these embodiments, the other illustrated layers are generally not present when the substrate is processed in the illustrated dispense module.

However, in other embodiments, adhesion promotion processing is performed after deposition of the BARC layer, thereby promoting the adhesion of the photoresist, top coat, and/or other layers to the wafer surface at peripheral regions of the wafer. Thus, as illustrated in FIG. 4, the adhesion between the coating layers radially outside the BARC is improved by the techniques described herein. Thus, an exemplary process flow could be BARC characterized by a predetermined radial coverage, adhesion promotion, photoresist with a radial coverage greater than the BARC, optional adhesion promotion, top coat with a radial coverage greater than or equal to the photoresist. One of ordinary skill in the art would recognize many variations, modifications, and alternatives.

As illustrated in FIG. 4, the application of the adhesion promoting chemical (e.g., HMDS) is limited to a peripheral region of the substrate, the wafer bevel, and the wafer apex. The chemical source (not shown) is provided in fluid communication with dispense line 410 and dispense nozzle 420. For example, the dispense module illustrated in FIG. 3 may be utilized. In the embodiment illustrated in FIG. 4, HMDS is discharged on to the peripheral edge and the bevel of the wafer through dispense nozzle 420.

Although FIG. 4 only illustrates a cross-section of the dispense nozzle 420, the geometry of the dispense nozzle is selected to provide for uniform dispense, controllable flow rates, repeatability, and the like. Additionally, although the HMDS illustrated in FIG. 4 is dispensed in a vertical direction, this is not required by embodiments of the invention. The dispense angle is selected in implementations as appropriate for limiting the HMDS to the peripheral region of the substrate. One of ordinary skill in the art would recognize many variations, modifications, and alternatives.

In order to further provide for spatial limitations in the HMDS wafer coverage, exhaust aperture 430 is provided radially adjacent to dispense nozzle 420. As illustrated in FIG. 4, the exhaust aperture 430 is positioned at a location just beyond the wafer edge. Thus, HMDS flowing from dispense nozzle 420 contacts the wafer edge and bevel and then flows radially outward prior to being exhausted from the wafer region. The combination of the supply and exhaust in the geometry illustrated in FIG. 4 effectively provides for pumping of the HMDS with a radially outward direction of flow.

Generally, the volume of the delivery area should be minimized to help reduce the processing time used to fill and purge the gases. Additionally, reductions in delivery volume will aid in preventing the surface of the wafer from being exposed to HMDS. As illustrated in FIG. 4, the bottom of the dispense apparatus includes a surface that is disposed in close proximity to the wafer, which reduces chamber volume and assists in preventing leaking of the dispensed gases toward the wafer center.

The dispense nozzle 420 and the exhaust aperture 430 are integrated into a single compound nozzle in a particular embodiment. Additionally, the dimensions of the dispense nozzle and the exhaust aperture in the direction orthogonal to view illustrated in FIG. 4 are selected depending on the particular application. For example, the exhaust aperture may extend to a greater distance, measured either along a tangent of the wafer edge or along the circumference of the wafer, than the extent of the dispense nozzle. Both the dispense nozzle and the exhaust aperture may be straight in the orthogonal direction, may curve to follow the circumference of the wafer, or may combine straight and curved sections as appropriate to the particular application.

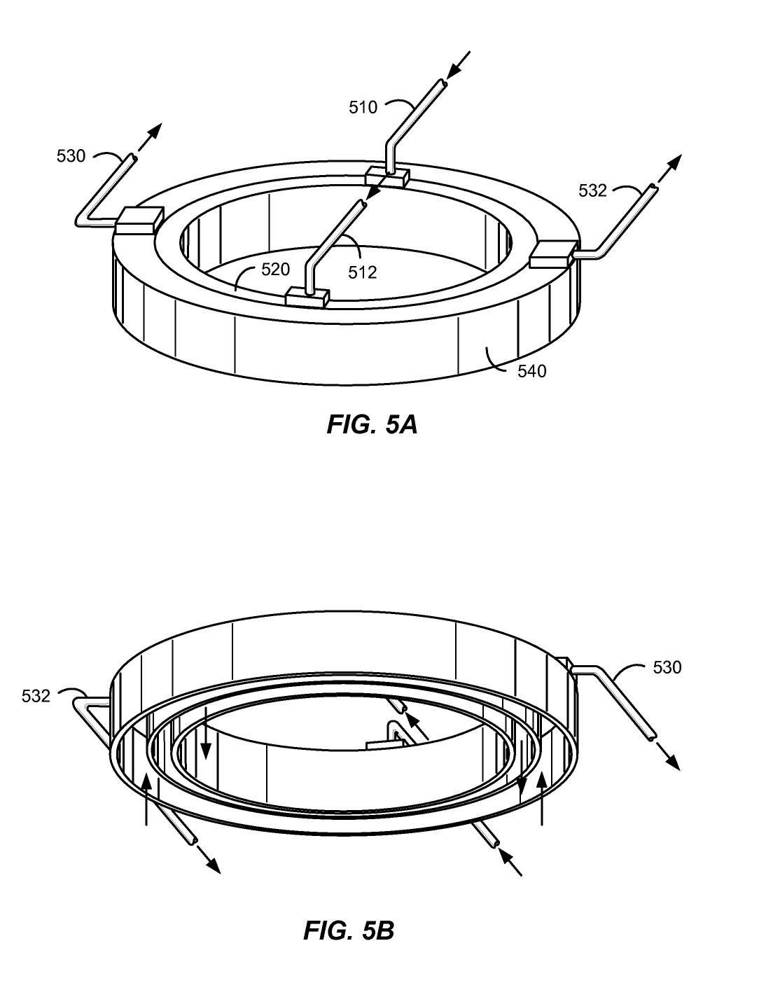

In a particular implementation, the dispense nozzle 420 and the exhaust aperture 430 are annular structures. FIGS. 5A and 5B are simplified perspective drawings illustrating an integrated dispense apparatus according to an embodiment of the present invention. FIG. 5A illustrates a top view of the integrated dispense apparatus and FIG. 5B illustrates a bottom view of the integrated dispense apparatus. In the particular implementation illustrated in FIGS. 5A and 5B, the inner circumference of the annular nozzle is slightly less than the circumference of the substrate and the outer circumference of the annular nozzle may be greater than or approximately equal to the circumference of the substrate. In some embodiments, the dispense nozzle and exhaust aperture may share common elements, for example a common wall forming the outer portion of the annular nozzle and the inner portion of the annular exhaust.

In the embodiment illustrated in FIGS. 5A and 5B, two inlet pipes 510 and 512 provide for a flow of the adhesion promoting chemical to the dispense nozzle 520. Additionally, two exhaust pipes 530 and 532 provide for flow of the exhaust through the exhaust nozzle 540 to an exhaust pump (not shown). Although the embodiment illustrated in FIGS. 5A and 5B utilize two inlet and two exhaust pipes, this is not required by embodiments of the present invention. Baffles or showerhead elements may be provided inside the dispense nozzle 520 to provide for a uniform flow of chemical as a function of radial position. Moreover, the dispense nozzle is illustrated as including vertical sides with an opening opposing the substrate. However, other embodiments utilize a dispense nozzle with surfaces oriented to direct the adhesion promoting chemical toward the edge of the substrate upon exiting the nozzle. One of ordinary skill in the art would recognize many variations, modifications, and alternatives.

It will be noted that the supply of adhesion promoting chemical and the exhaust thereof can be performed with multiple combinations of ring plenums on the wafer edge. Merely by way of example, the exhaust could be positioned on top and the delivery on the bottom or vice versa. Other geometries are also included within the scope of the present invention.

In contrast with conventional dispense systems for adhesion promoting chemicals, the flow path between the furthest portion of the dispense nozzle and the exhaust aperture is less than the radius of the substrate. Typically, the dispense nozzle, such as illustrated in U.S. Patent Application Publication No. 2006/0291854, entitled “Substrate Processing Apparatus,” which is commonly assigned and herein incorporated by reference for all purposes, includes fluid sources arrayed across a faceplate. Thus, with sources of the chemical over the center of the substrate, the distance from such sources to the exhaust aperture is greater than the substrate radius. In embodiments of the present invention, this distance is greatly reduced, for example to less than 100 mm. In a particular embodiment, the flow path from the farthest portion of the dispense nozzle to a corresponding exhaust aperture is less than 10 mm. As a results, embodiments of the present invention provide for increases in the uniformity of HMDS concentration as a function of position measured in the plane of the substrate.

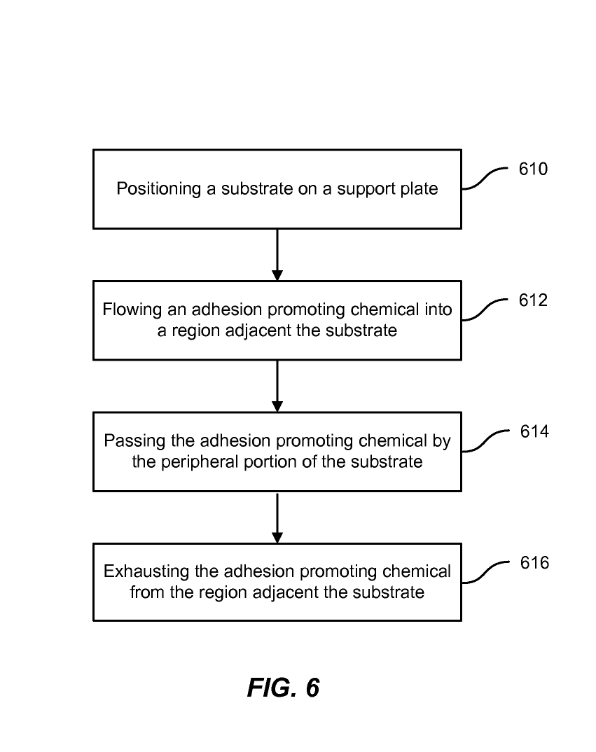

FIG. 6 is a simplified flowchart illustrating a method of dispensing an adhesion promoting chemical according to an embodiment of the present invention. The method 600 includes positioning a substrate on a support plate in an adhesion treatment unit 610. Generally, the substrate is provided to the adhesion treatment unit by a robot, for example, a central robot in a track lithography tool. The substrate may be a semiconductor substrate or wafer, which is horizontally positioned on the support plate. The adhesion promoting chemical is caused to flow into a region adjacent the substrate 612. The flow of the adhesion promoting chemical causes contact between the adhesion promoting chemical and a peripheral portion of the substrate. As illustrated in FIG. 4, a dispense nozzle may be used to dispense HMDS onto the peripheral portion of the substrate. Generally, the peripheral region of the substrate includes the outer 10 mm of the substrate as measured from the substrate apex. In a specific embodiment, the peripheral region includes the outer 5 mm of the substrate as measured from the substrate apex. In another specific embodiment, the peripheral region includes the outer 2 mm of the substrate as measured from the intersection of the substrate topside and the wafer bevel.

The adhesion promoting chemical passes by the peripheral portion of the substrate with a generally radially outward flow 614. Thus, the adhesion promoting chemical, for example, HMDS, passes by the edge of the wafer and into the region surrounding the wafer. The adhesion promoting chemical is exhausted from the region adjacent the substrate 616. Thus, by introducing the adhesion promoting chemical at the periphery of the substrate and providing a radially outward flow path to the exhaust, the chemical treats the periphery of the substrate with little or no treatment provided to central portions of the substrate. In some embodiments, the region adjacent the substrate is evacuated using one or more vacuum sources, such as that coupled to the exhaust aperture, to provide a pressure in the region adjacent the substrate less than atmospheric pressure. Thus, depending on the application, the chamber may be operated under reduced pressure (e.g., vacuum conditions) during some or all of the process. One of ordinary skill in the art would recognize many variations, modifications, and alternatives.

As described in relation to FIGS. 5A and 5B, the dispense nozzle and the exhaust aperture may be formed in an annular configuration with the inner circumference of the dispense nozzle being less than the substrate circumference and the outer circumference of the dispense nozzle being greater than or approximately equal to the substrate circumference. In some implementations, the outer wall of the dispense nozzle is also the inner wall of the exhaust aperture.

It should be appreciated that the specific steps illustrated in FIG. 6 provide a particular method of performing a lithography process on a substrate according to an embodiment of the present invention. Other sequences of steps may also be performed according to alternative embodiments. For example, alternative embodiments of the present invention may perform the steps outlined above in a different order. Moreover, the individual steps illustrated in FIG. 6 may include multiple sub-steps that may be performed in various sequences as appropriate to the individual step. Furthermore, additional steps may be added or removed depending on the particular applications. One of ordinary skill in the art would recognize many variations, modifications, and alternatives.

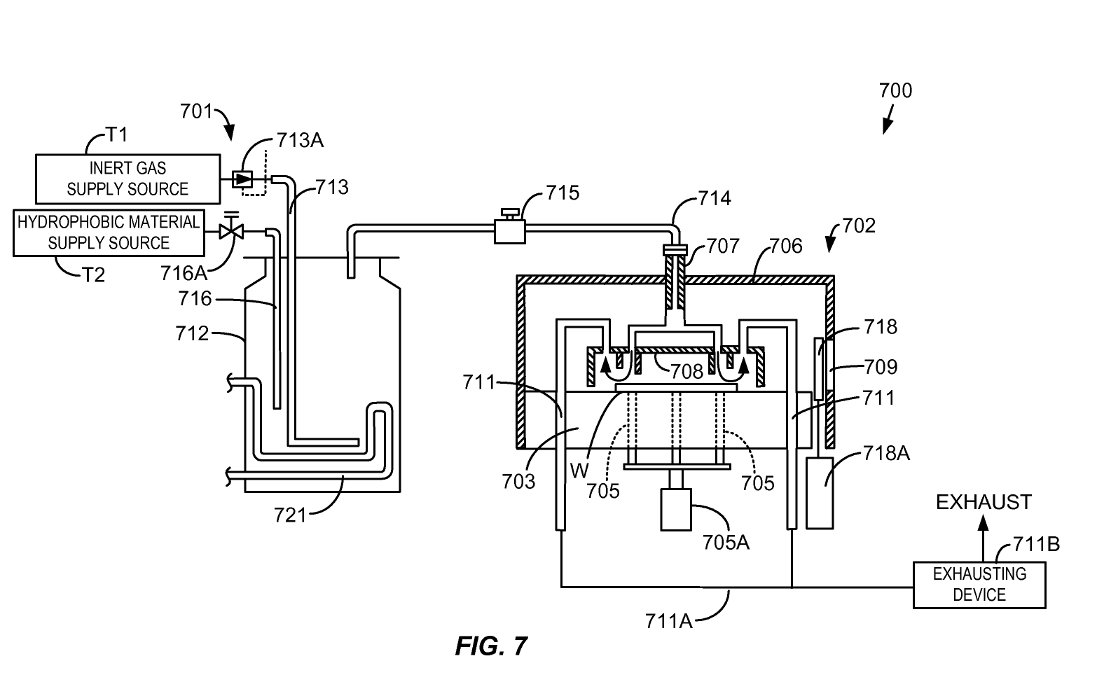

FIG. 7 is a simplified schematic diagram illustrating a dispense module according to an embodiment of the present invention. In a particular embodiment, the dispense module shares common design elements with the hydrophobic processing unit (HYP) described in U.S. Patent Application Publication No. 2006/0291854, entitled “Substrate Processing Apparatus,” commonly assigned and herein incorporated by reference for all purposes. As illustrated in FIG. 7, the dispense module 700 includes a vaporization processing device 701, which vaporizes the adhesion promoting material, and an adhesion promoting material supply device 702, which supplies the adhesion promoting material vaporized in the vaporization processing device 701 to the substrate W. For simplicity in describing FIG. 7, the adhesion promoting material will be described in terms of HMDS.

The vaporization processing device 701 includes a liquid storage tank 712 for storing the HMDS. The liquid storage tank 712 is connected to an inert gas supply source T1 through an inert gas pipe 713, and to an HMDS supply source T2 through an HMDS supply pipe 716. The inert gas supply pipe 713 is provided with a regulator 713A, and then an inert gas is supplied from the inert gas supply source T1 to the liquid storage tank 712 under a certain pressure. The HMDS supply pipe 716 is provided with a valve 716A and HMDS is supplied from the HMDS supply source T2 to the liquid storage tank 712 by opening the valve 716A.

A heat exchange coil 721 is provided at the lower portion of the liquid storage tank 712 so that the temperature of the heat exchange coil 721 can be increased in order to vaporize the HMDS in the liquid storage tank 712. The HMDS supply device 702 has a substrate platform plate 703, which heats the substrate W mounted on its top surface to a predetermined temperature. A plurality of lift pins 705 are provided to pass through the substrate platform plate 703 in the vertical direction. The lift pins 705 are vertically actuated by a lift pin driving mechanism 705A.

A cover 706 is provided over the substrate platform plate 703. A tubular supporting member 707 is provided so as to move up and down through the center of the cover 706 in the vertical direction. A pipe 714 is connected to the upper end of the supporting member 707 in fluid communication with the liquid storage tank 712 in the vaporization processing device 701. The pipe 714 is provided with a valve 715 to control the flow rate of the HMDS into the HMDS supply device 702.

In an embodiment, the integrated dispense apparatus illustrated in FIGS. 5A and 5B is mounted inside the cover 206 and utilized to dispense the HMDS. As illustrated in FIG. 7, the integrated dispense apparatus 708 is coupled to the lower end of supporting member 707. Vertical motion of the integrated dispense apparatus 708 is provided so that the integrated dispense apparatus 708 can move with respect to the substrate platform plate 703. Exhaust flowing through exhaust tubes 711 is exhausted using pump 711B. A side of the cover 706 has transfer opening 709 to provide for loading and unloading of the substrate W. A shutter 718 covers the transfer opening 709 and is actuated by driving device 718A. Although not illustrated controller 160 may be used to control the operation of the dispense module illustrated in FIG. 7.

While the present invention has been described with respect to particular embodiments and specific examples thereof, it should be understood that other embodiments may fall within the spirit and scope of the invention. The scope of the invention should, therefore, be determined with reference to the appended claims along with their full scope of equivalents.

What is claimed is:

1. A system for dispensing an adhesion promoting chemical, the system comprising:
a support plate configured to support a substrate;
a dispense nozzle in fluid communication with a source of the adhesion promoting chemical, wherein the dispense nozzle is positioned adjacent a peripheral portion of the substrate and at a first radial distance; and
an exhaust aperture in fluid communication with a system exhaust, wherein the exhaust aperture is positioned adjacent to dispense nozzle and at a second radial distance greater than the first radial distance.

2. The system of claim 1 wherein the adhesion promoting chemical comprises at least one of HMDS, TMSDEA, or DEATS.

3. The system of claim 1 wherein the support plate is configured to support the substrate in a substantially horizontal configuration.

4. The system of claim 1 wherein the support plate comprises one or more thermal elements.

5. The system of claim 4 wherein the support plate comprises a bake plate.

6. The system of claim 1 wherein the second radial distance is greater than half a diameter of the substrate.

7. The system of claim 1 wherein the dispense nozzle comprises an annular nozzle having an inner circumference less than a circumference of the substrate and an outer circumference greater than the inner circumference.

8. The system of claim 7 wherein the exhaust aperture comprises an annular aperture having an inner circumference greater than the inner circumference of the annular nozzle.

9. A method of treating a substrate with an adhesion promoting chemical, the method comprising:
positioning the substrate on a support plate;
flowing the adhesion promoting chemical into a region adjacent the substrate, thereby making contact between the adhesion promoting chemical and a peripheral portion of the substrate while maintaining a central portion of the substrate substantially free from contact with the adhesion promoting chemical;
passing the adhesion promoting chemical by the peripheral portion of the substrate; and
exhausting the adhesion promoting chemical from the region adjacent the substrate.

10. The method of claim 9 wherein the adhesion promoting chemical comprises HMDS.

11. The method of claim 9 further comprising heating the substrate to a temperature in a range from 90° to 150°.

12. The method of claim 9 wherein the peripheral portion of the substrate comprises an outer 5 mm of the substrate.

13. The method of claim 12 wherein the peripheral portion of the substrate comprises an outer 2 mm of the substrate.

14. The method of claim 9 wherein the substrate comprises a semiconductor wafer.

15. The method of claim 9 further comprising evacuating the region adjacent the substrate to provide a pressure in the region adjacent the substrate less than an atmospheric pressure.

16. The method of claim 9 wherein the dispense nozzle comprises an annular nozzle having an inner circumference less than a circumference of the substrate and an outer circumference greater than the inner circumference.

17. The method of claim 16 wherein the exhaust aperture comprises an annular aperture having an inner circumference greater than the inner circumference of the annular nozzle.

18. A track lithography tool comprising:
a robot;
a thermal treatment unit serviced by the robot;
a coating unit serviced by the robot; and
an adhesion treatment unit serviced by the robot, the adhesion treatment unit comprising:
a support plate configured to support a substrate;
a dispense nozzle in fluid communication with a source of the adhesion promoting chemical, wherein the dispense nozzle is positioned adjacent a peripheral portion of the substrate and at a first radial distance; and
an exhaust aperture in fluid communication with a system exhaust, wherein the exhaust aperture is positioned adjacent to dispense nozzle and at a second radial distance greater than the first radial distance.

19. The track lithography tool of claim 18 wherein the adhesion promoting chemical comprises HMDS.

20. The track lithography tool of claim 18 wherein the dispense nozzle comprises an annular nozzle having an inner circumference less than a circumference of the substrate and an outer circumference greater than the inner circumference.

21. The track lithography tool of claim 20 wherein the exhaust aperture comprises an annular aperture having an inner circumference greater than the inner circumference of the annular nozzle.
